(19) United States
(12) Patent Application Publication
(10) Pub. No.: US 2021/0210645 A1
(43) Pub. Date: Jul. 8, 2021

(54) CHALCOGENIDE SOLAR CELL HAVING TRANSPARENT CONDUCTING OXIDE BACK CONTACT, AND METHOD OF MANUFACTURING THE CHALCOGENIDE SOLAR CELL

(71) Applicant: KOREA INSTITUTE OF SCIENCE AND TECHNOLOGY, Seoul (KR)

(72) Inventors: Jeung Hyun JEONG, Seoul (KR); Won Mok KIM, Seoul (KR); Jong Keuk PARK, Seoul (KR)

(21) Appl. No.: 16/081,569

(22) PCT Filed: Oct. 19, 2017
(86) PCT No.: PCT/KR2017/011586

§ 371 Date: Aug. 31, 2018

(30) Foreign Application Priority Data
Sep. 14, 2017 (KR) 10-2017-0118058

(51) Int. Cl. H01L 31/032; H01L 31/0224; H01L 31/18

(52) U.S. Cl. CPC H01L 31/0322; H01L 31/1884; H01L 31/022441; H01L 31/022475

(57) ABSTRACT

Provided is a chalcogenide solar cell including a substrate, a transparent conducting oxide (TCO) back contact provided on the substrate, a chalcogenide light absorbing layer provided on the TCO back contact and including at least copper (Cu), gallium (Ga), and silver (Ag), and a TCO front contact provided on the chalcogenide light absorbing layer, wherein a Cu-rich region having a content of Cu higher than an average Cu content of the chalcogenide light absorbing layer is provided at an interface where the chalcogenide light absorbing layer is in contact with the TCO back contact.

### TECHNICAL FIELD

The present invention relates to a method of manufacturing a chalcogenide solar cell, and more particularly, to a method of forming a chalcogenide absorber layer on a transparent conducting oxide (TCO) back contact, and a solar cell including a cell structure manufactured using the method.

### BACKGROUND ART

Solar cells are classified in various ways depending on a material used for an absorber layer. Although most solar cells use silicon (Si) for an absorber layer, chalcogenide solar cells, which use a high-efficiency chalcogenide material for an absorber layer, attract attention of people for research.

Chalcogenide is a compound including chalcogen elements, sulfur (S), selenium (Se), and tellurium (Te), and chalcogenide solar cells representatively use CuInSe₂ (CIS), Cu(In₁₋ₓ,Gaₓ)(Se_{y},S_{1-y})₂ (CIGS), CuGaSe₂ (CGS), etc.

As a representative chalcogenide solar cell, a CIGS thin film solar cell is capable of achieving high photoelectric conversion efficiency due to a high absorption rate and excellent semiconductor characteristics, and thus is regarded as a next- generation low-cost high-efficiency solar cell. A CIGS thin film may grow on a metal substrate or a polymer substrate as well as a hard glass substrate, and thus may be developed to a flexible solar cell. Furthermore, the CIGS thin film solar cell may freely change a bandgap by changing a Ga(In+Ga) ratio or a Se/(Se+S) ratio, and thus is advantageous to select an absorber layer material corresponding to a light spectrum of sunlight or an external light source. In particular, a Se-based solar cell may change a bandgap from 1.0 eV to 1.7 eV based on an In/(In+Ga) ratio. The CIGS thin film solar cell currently achieves the highest photovoltaic conversion efficiency in a bandgap range of 1.1 eV to 1.2 eV, but may achieve higher performance in a composition corresponding to a bandgap range of 1.4 eV to 1.5 eV capable of achieving theoretically the highest photovoltaic conversion efficiency, and may be used for a tandem solar cell using a 1.7 eV bandgap material appropriate for an upper cell of a two-junction tandem solar cell.

A Cu(In₁₋ₓ,Gaₓ)(Se_{y},S_{1-y})₂ light absorbing layer, which is a main element of the CIGS thin film solar cell, may be produced using various methods. A vacuum deposition method such as co-evaporation or sputter-selenization, or a non-vacuum process method including a precursor forming operation and a selenization operation based on powder sintering, electroplating, reaction solution, or the like may be used. A process capable of achieving the highest photovoltaic conversion performance is co-evaporation. Particularly, 3-stage co-evaporation (see FIG. 1) including a recrystallization promoting operation based on excess Cu is used. In this process, initially, an (In,Ga)₂Se₃ precursor is formed by depositing indium (In), gallium (Ga), and selenium (Se) in a temperature range of 300° C. to 400° C., and copper (Cu) and Se are deposited on and diffused into the (In,Ga)₂Se₃ precursor by increasing the temperature to 400° C. to 580° C., thereby changing the (In,Ga)₂Se₃ precursor to a Cu(In,Ga)Se₂ structure. In this case, when Cu composition is beyond its stochiometry,the speed of atoms motion within CIGS is increased , promoting the recrystallization of CIGS, and thus a high crystallinity of CIGS thin film may be obtained. Thereafter, a Cu-poor Cu(In,Ga)Se₂compound is obtained by additionally and partially depositing In, Ga, and Se, because CIGS achieves excellent p-doped semiconductor characteristics when the content of Cu is slightly less than a stoichiometric composition. A right side of FIG. 1 shows cross-sectional electron microscopic images of CIGS formed using 3-stage co-evaporation and a CIGS thin film formed using single-stage co-evaporation. It is shown that a grain size of CIGS formed using 3-stage co-evaporation is much greater than the grain size of the CIGS thin film formed using single-stage co-evaporation.

Since a CIGS light absorbing layer may easily change a bandgap by changing its composition as described above, a tandem cell including a CuGaSe₂ solar cell having a bandgap of 1.7 eV, as an upper cell, and including a CIGS solar cell having a bandgap of 1.1 eV, as a lower cell may be manufactured, and research is being actively conducted on the tandem cell. As the photovoltaic conversion efficiency of crystalline Si (c-Si) solar cells currently reaches its limit, a hybrid tandem solar cell including a c-Si solar cell as a lower cell and including a CIGS solar cell as an upper cell attracts much attention of people. The c-Si solar cell employing a sandwich cell structure (bottom contact/Si/top contact) having excellent cost competitiveness has increased its photovoltaic conversion efficiency to about 23% to 24% by applying selective contact technology or front/back passivation technology. However, to exceed a milestone of 25%, complex and high-cost process technology such as interdigitated back contact (IBC) technology for providing both front and back contacts on a single surface or HIT technology using amorphous Si (a-Si) thin film passivation technology is necessary. The hybrid tandem solar cell manufactured by sequentially stacking a transparent contact and a high-bandgap CIGS thin film on an existing sandwich c-Si cell structure is a promising technology due to its high cost competitiveness, high efficiency equal to or greater than 30%, and good compatibility with the existing Si industry.

A major next-generation application field of the CIGS thin film solar cell is a see-through photovoltaic module. It is necessary to develop a high-efficiency and transparent solar cell applicable to regions receiving daylight and occupying large areas, e.g., windows of buildings, balconies, and sunroofs of vehicles. An a-Si solar cell, a dye-sensitized solar cell (DSSC), and an organic solar cell have been developed so far for the application of the see-through photovoltaic module, but are not broadly used due to very low efficiency or lack of stability. Due to its high efficiency of 22.6%, the CIGS thin film solar cell will have excellent competitiveness if the CIGS thin film solar cell is developed to a structure capable of transmitting light.

To make use of the CIGS thin film solar cell as an upper cell of a tandem solar cell or as a transparent solar cell as described above, all contacts should be transparent to incident light. In general, the CIGS thin film solar cell includes a glass substrate, a molybdenum (Mo) back contact, a CIGS light absorbing layer, a buffer layer (e.g., CdS, Zn(S,O), ZnSnO, or ZnMgO), and transparent conducting oxide (TCO) (e.g., aluminum-doped ZnO (AZO), bismuth-doped ZnO (BZO), or indium tin oxide (ITO)). Therefore, to use the CIGS thin film solar cell in the above applications, the Mo metal back contact incapable of transmitting light should be replaced by a TCO contact (see (a) of FIG. 2).

However, when the TCO back contact is used, Ga in CIGS layer reacts with oxygen (O) in TCO while the CIGS is deposited at high temperature, and thus a gallium oxide (GaOx) secondary phase having various characteristics is formed at the TCO back contact/CIGS interface (see (b) of FIG. 2). Since GaOx is a high-resistivity n-doped semiconductor, a strong inverse diode for disturbing carrier transport is formed on the surface of the back contact as shown in (c) of FIG. 2. Formation of the secondary phase is facilitated in proportion to a CIGS deposition temperature, but the CIGS light absorbing layer of higher quality can be obtained at a higher process temperature, thereby causing a dilemma.

A CIGS light absorbing layer having a low bandgap of about 1.1 eV to 1.2 eV due to a high content of Indium may achieve high photovoltaic conversion efficiency even at a process temperature equal to or lower than 450° C., and thus Ga—O reaction may be partially suppressed without efficiency loss using such a low-temperature process. However, since a GaOx secondary phase is also formed at such a low process temperature depending on TCO thin film characteristics, the low temperature process may not be a perfect solution. Furthermore, a low-temperature process may not be applied to a CIGS or CGS light absorbing layer having a very high content of Ga and having a bandgap of about 1.7 eV because defects are greatly increased when the process temperature is lowered. Therefore, development of a method capable of suppressing Ga—O reaction at an interface between a TCO back contact and a CIGS light absorbing layer at a high temperature equal to or higher than 550° C. is necessary. The above-described problem commonly occurs in chalcogenide solar cells including Ga as a main component, e.g., CIGS and CGS solar cells, and should be solved to manufacture a see-through photovoltaic module.

### DETAILED DESCRIPTION OF THE INVENTION

### Technical Problem

The present invention provides a manufacturing method capable of increasing photovoltaic conversion efficiency of a copper indium gallium selenide (CIGS) thin film solar cell having a transparent conducting oxide (TCO) back contact by suppressing formation of gallium oxide (GaOx) at an interface between the back contact and a chalcogenide light absorbing layer including copper (Cu) and gallium (Ga) when the light absorbing layer is formed.

### Technical Solution

According to an aspect of the present invention, a chalcogenide solar cell including a substrate, a transparent conducting oxide (TCO) back contact provided on the substrate, a chalcogenide light absorbing layer provided on the TCO back contact and including at least copper (Cu), gallium (Ga), and silver (Ag), and a TCO front contact provided on the chalcogenide light absorbing layer, wherein a Cu-rich region having a content of Cu higher than an average Cu content of the chalcogenide light absorbing layer is provided at an interface where the chalcogenide light absorbing layer is in contact with the TCO back contact.

Gallium oxide (GaOx) having a thickness equal to or less than 3 nm may be provided on the TCO back contact.

The chalcogenide light absorbing layer may include Cu(InₓGa₁₋ₓ)(Se_{y},S_{1-y}) (0.2<x≤1, 0≤y≤1).

The Cu-rich region may have a thickness range of 2 nm to 10 nm.

A content of Ag in the chalcogenide light absorbing layer may be greater than 0 atomic percent (at %) and equal to or less than 2 at %.

The chalcogenide solar cell may further include a molybdenum (Mo) layer between the Cu-rich region and the TCO back contact, and the Mo layer may be provided as a pattern generated by coating only a part of the TCO back contact and including a window capable of transmitting light therethrough.

One or more of titanium oxide (TiOx), niobium-doped titanium oxide (TiNbOx), Mo(S, Se)₂, and MoO₃ layers may be provided between the Cu-rich region and the TCO back contact.

The content of Cu of the Cu-rich region may be higher than the average Cu content of the chalcogenide light absorbing layer by 10 at % to 20 at %.

The substrate may include a transparent substrate or a crystalline silicon (c-Si) substrate.

According to another aspect of the present invention, a method of manufacturing a chalcogenide solar cell includes forming a transparent conducting oxide (TCO) back contact on a first surface of a substrate, forming a silver (Ag) precursor layer on the TCO back contact, forming a chalcogenide light absorbing layer including copper (Cu) and gallium (Ga), on the TCO back contact, and forming a TCO front contact on the chalcogenide light absorbing layer.

In this case, the forming of the chalcogenide light absorbing layer may include diffusing the Ag precursor layer into the chalcogenide light absorbing layer, and forming a Cu-rich region having a content of Cu higher than an average Cu content of the chalcogenide light absorbing layer, at an interface where the chalcogenide light absorbing layer is in contact with the TCO back contact.

The chalcogenide light absorbing layer may include Cu(InₓGa₁₋ₓ)(Se_{y},S_{1-y}) (0.2<x≤1, 0≤y≤1).

The forming of the chalcogenide light absorbing layer may include a first stage for forming a gallium selenide layer or a gallium sulfide layer by depositing Ga and selenium (Se), or Ga and sulfur (S) on the TCO back contact, and a second stage for coating and diffusing Cu and Se, or Cu and S on and into the gallium selenide layer or the gallium sulfide layer.

The forming of the chalcogenide light absorbing layer may include a first stage for forming an indium gallium selenide layer or an indium gallium sulfide layer by depositing Ga, indium (In) and Se, or Ga, In and S on the TCO back contact, and a second stage for coating and diffusing Cu and Se, or Cu and S on and into the indium gallium selenide layer or the indium gallium sulfide layer.

The diffusing of the Ag precursor layer into the chalcogenide light absorbing layer and the forming of the Cu-rich region may be performed in the second stage.

The first stage may be performed at a temperature range of 300° C. to 400° C.

The second stage may be performed at a temperature range of 430° C. to 600° C.

The method may further include forming a molybdenum (Mo) layer as a pattern generated by coating only a part of the TCO back contact and including a window capable of transmitting light therethrough, after the TCO back contact is formed.

The Ag precursor layer may include pure Ag.

The Ag precursor layer may include an alloy of Mo and Al, and may be formed as a pattern generated by coating only a part of the TCO back contact and including a window capable of transmitting light therethrough.

The method may further include forming one or more of TiOx, TiNbOx, Mo(S, Se)₂, and MoO₃ layers on the TCO back contact after the TCO back contact is formed.

The Ag precursor layer may have a thickness range of 1 nm to 20 nm.

The Ag precursor layer may have a thickness range of 10 nm to 20 nm.

### Advantageous Effects

When a solar cell is manufactured by depositing a silver (Ag) precursor on a transparent conducting oxide (TCO) back contact and then forming (In,Ga)₂Se₃ or Ga₂Se₃ and depositing copper (Cu) and selenium (Se) thereon to form a copper indium gallium selenide (CIGS) or copper gallium selenide (CGS) light absorbing layer, formation of gallium oxide (GaOx) at an interface between the TCO back contact and the CIGS or CGS light absorbing layer may be greatly suppressed. According to conventional technology, a high-resistivity n-doped semiconductor, GaOx is provided at the back of a p-doped semiconductor, CIGS or CGS and thus disturbs carrier transport. However, according to the present invention, since GaOx is completely removed and the interface between the transparent back contact and the CIGS or CGS light absorbing layer forms an ohmic junction, photovoltaic conversion efficiency may be increased.

In addition, according to the present invention, a TCO thin film such as indium tin oxide (ITO) may be provided as an intermediate contact which serves as a tunnel layer when a crystalline Si (c-Si) solar cell and a CGS thin film solar cell are integrated into a tandem cell.

When a molybdenum (Mo) layer having a preset or random nano-sized or micro-sized pattern is provided between the TCO back contact and Ag, light may be transmitted through an open part of the Mo layer and, at the same time, a mechanical interlocking effect may be improved and interface adhesion may be increased between the TCO back contact and CIGS or CGS.

When TiOx or TiNbOx is provided between the TCO back contact and Ag, chemical wetting may be improved and interface adhesion may be increased between the TCO back contact and the CIGS or CGS light absorbing layer.

When Mo(S,Se)₂ or MoO₃ is provided between the TCO back contact and Ag, electrical characteristics of the interface between the TCO back contact and the CIGS or CGS light absorbing layer may be improved to be more ohmic.

### DESCRIPTION OF THE DRAWINGS

FIG. 1 shows a copper indium gallium selenide (CIGS) light absorbing layer deposition method using 3-stage co-evaporation, and an effect thereof.

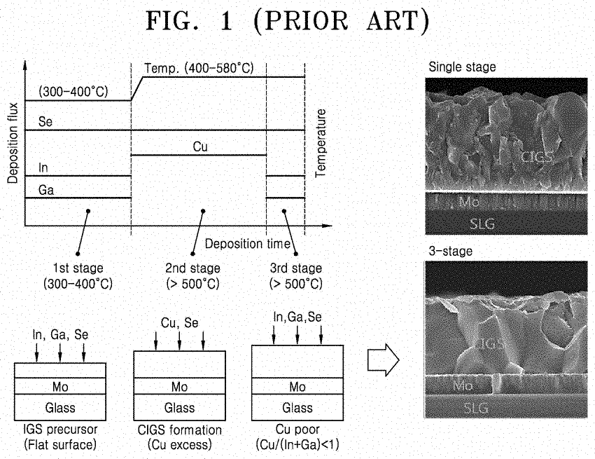

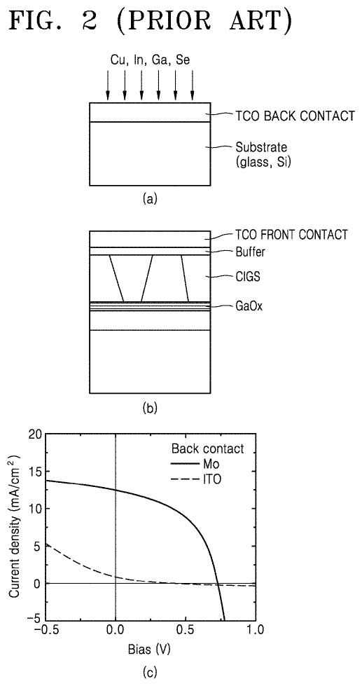

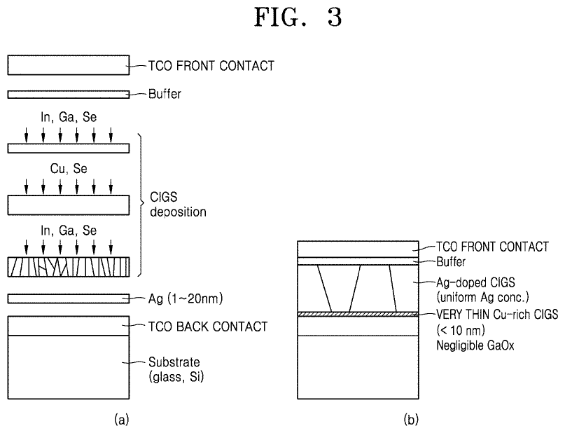

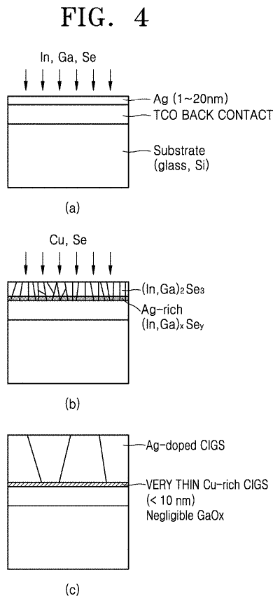

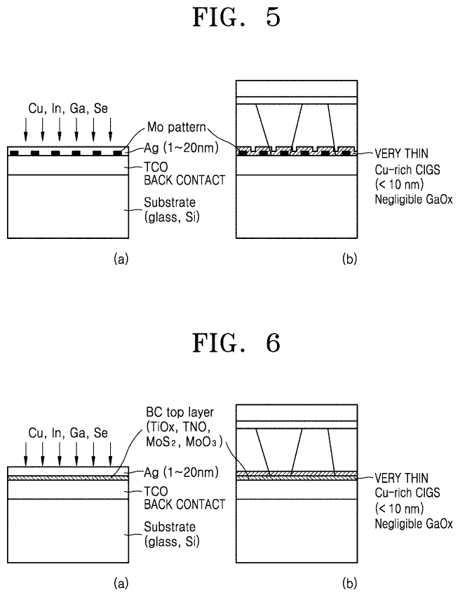

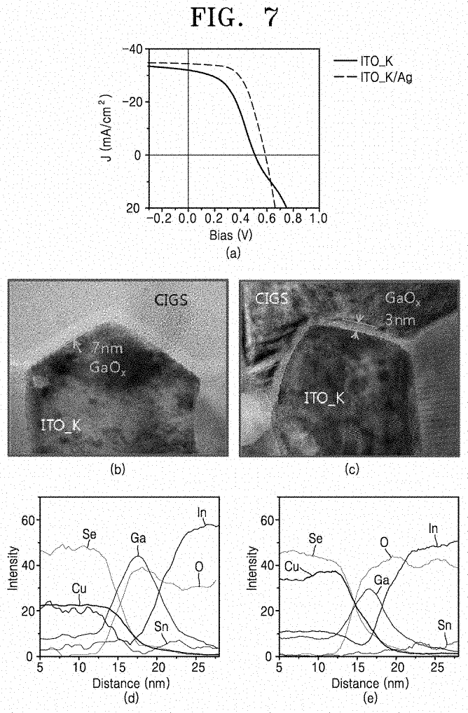

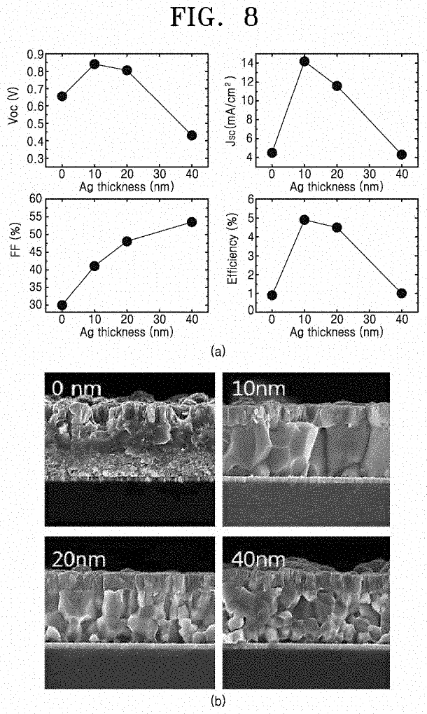

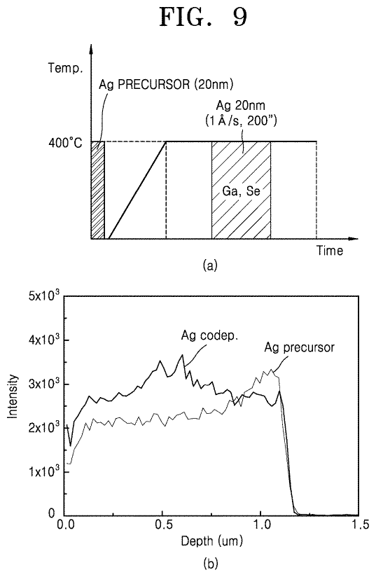

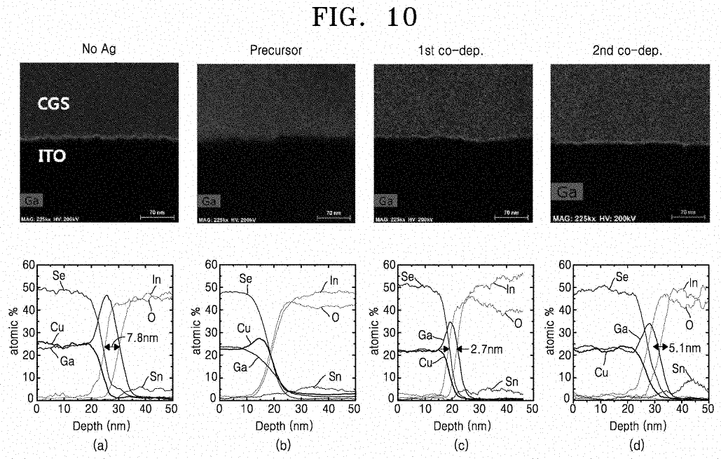

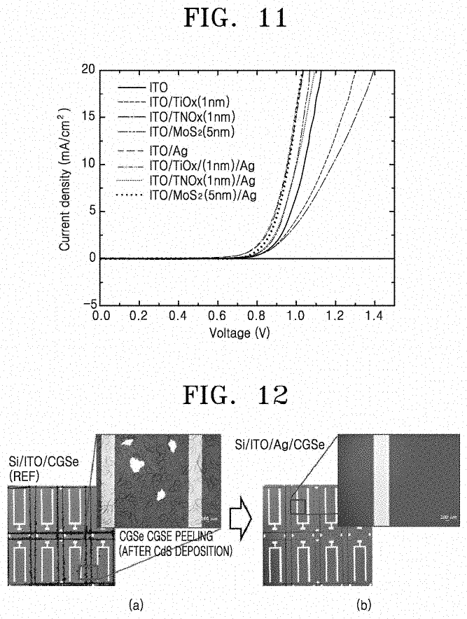

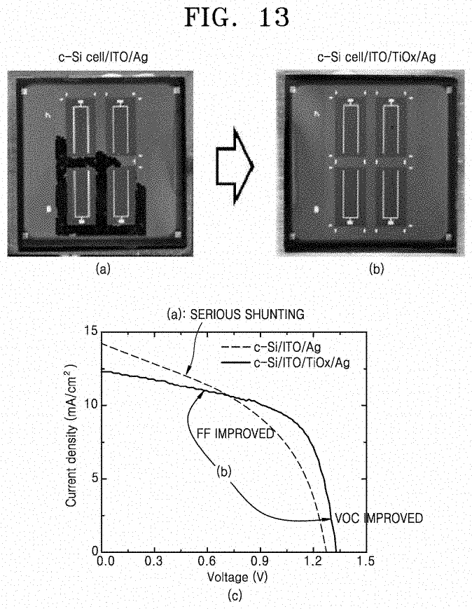

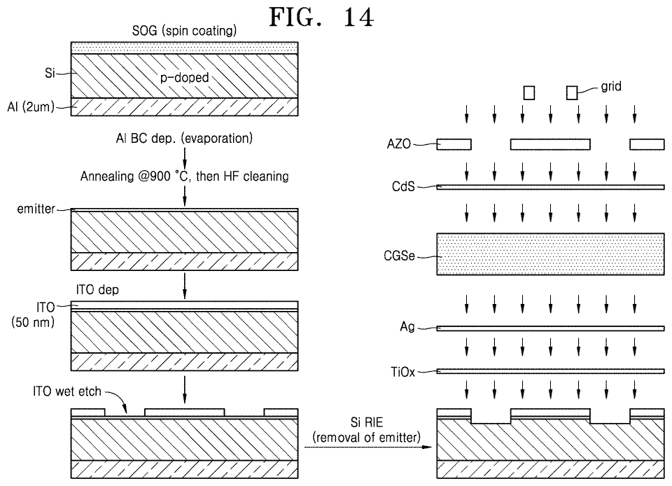

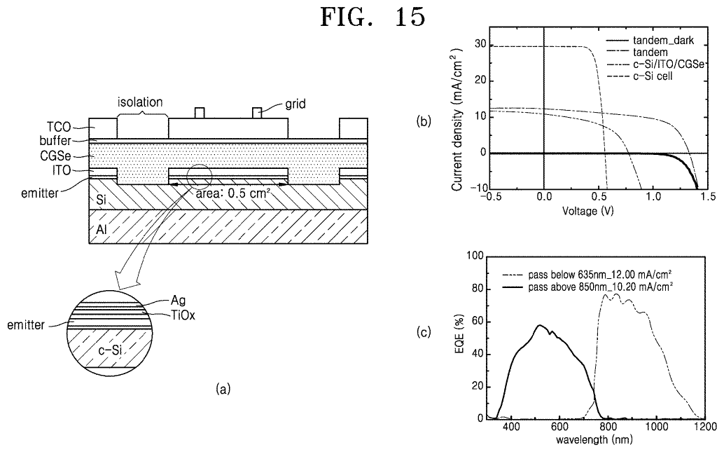

(a) and (b) of FIG. 2 show a gallium oxide (GaOx) secondary phase formed while CIGS is being deposited on a transparent conducting oxide (TCO) back contact, and (c) of FIG. 2 shows an effect of an indium tin oxide (ITO) back contact on a j-V curve.

(a) of FIG. 3 shows a solar cell manufacturing method according to an embodiment of the present invention, and (b) of FIG. 3 shows a cell structure of a solar cell according to an embodiment of the present invention.

(a) to (c) of FIG. 4 show the function of a silver (Ag) precursor at a back contact interface while CIGS is being formed.

(a) and (b) of FIG. 5 show a solar cell manufacturing method for depositing an Ag precursor on a molybdenum (Mo) metal pattern partially deposited on a TCO back contact, and a cell structure thereof.

(a) and (b) of FIG. 6 show a solar cell manufacturing method for forming one of TiOx, TiNbOx, Mo(S, Se)₂, and MoO₃ layers on a TCO back contact and depositing an Ag precursor on the TiOx, TiNbOx, Mo(S, Se)₂, or MoO₃ layer, and a cell structure thereof.

FIG. 7 shows the influence of an Ag precursor having a thickness of 10 nm, on a CIGSe (Ga/(In+Ga)=0.35) solar cell formed on an ITO back contact. Specifically, (a) of FIG. 7 shows white light current-voltage characteristics, (b) of FIG. 7 shows an ITO/CIGSe interface structure formed by not depositing an Ag precursor, and a composition distribution thereof, and (c) of FIG. 7 shows an ITO/CIGSe interface structure formed by depositing an Ag precursor having a thickness of 10 nm, and a composition distribution thereof.

(a) of FIG. 8 shows cell efficiency of a copper gallium selenide (CGSe) solar cell based on the thickness of an Ag precursor on an ITO back contact, and (b) of FIG. 8 shows cross-sectional scanning electron microscopic (SEM) images of solar cells.

(a) of FIG. 9 shows Ga₂Se₃ forming methods at a process temperature of 400° C. based on Ag doping methods, and (b) of FIG. 9 comparatively shows Ag distributions of a Ga₂Se₃ layer formed by depositing an Ag precursor, and a Ga₂Se₃ layer formed by co-depositing Ag in the middle of Ga₂Se₃ deposition.

FIG. 10 shows composition distributions near an ITO/CGSe interface based on Ag supplying methods. Specifically, (a) of FIG. 10 shows a result of a method of not doping Ag, (b) of FIG. 10 shows a result of a method of depositing an Ag precursor, (c) of FIG. 10 shows a result of a method of co-evaporating Ag in the middle of a first stage for depositing Ga₂Se₃, and (d) of FIG. 10 shows a result of a method of co-evaporating Cu and Ag at the beginning of a second stage.

FIG. 11 comparatively shows dark current flow characteristics (j-V) of solar cells using samples prepared by forming TiOx (1 nm), TiNbOx (TNO) (1 nm), and MoS₂ (5 nm) on an ITO back contact and then depositing an Ag precursor on TiOx, TNO, and MoS₂.

(a) of FIG. 12 shows a problem of interface peeling when a CGSe cell is formed on a Si substrate, and (b) of FIG. 12 shows increase in interface adhesion due to an Ag precursor.

(a) of FIG. 13 shows a problem of interface peeling when a CGSe cell is formed on ITO, (b) of FIG. 13 shows increase in interface adhesion when TiOx is formed between ITO and an Ag precursor, and (c) of FIG. 13 is a graph comparatively showing cell efficiency characteristics of solar cells.

FIG. 14 shows a process of manufacturing a crystalline Si (c-Si)/ITO/CGSe tandem cell.

(a) of FIG. 15 shows a tandem cell structure according to an embodiment of the present invention, (b) of FIG. 15 shows a current-voltage curve of the tandem cell structure, and (c) of FIG. 15 shows quantum efficiency.

### BEST MODE

Hereinafter, the present invention will be described in detail by explaining embodiments of the invention with reference to the attached drawings. The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the sizes of elements may be exaggerated or reduced for convenience of explanation.

Throughout the specification and the claims, it will be understood that when an element, such as a layer or a region, is referred to as being “on” another element, it may be directly on the other element or intervening elements may be present. In contrast, when an element is referred to as being “directly on” another element, there are no intervening elements or layers present.

In various embodiments of the present invention to be described below, a copper indium gallium selenide (CIGS) solar cell will be described as an example of a chalcogenide solar cell including copper (Cu) and gallium (Ga). However, the embodiments of the present invention may be equally applied to other chalcogenide solar cells including Cu and Ga, e.g., a copper gallium selenide (CGS) solar cell.

FIG. 3 shows cross-sectional views showing a cell manufacturing process and a cell structure according to a first embodiment of the present invention. A transparent conducting oxide (TCO) back contact is deposited on a substrate, and a silver (Ag) precursor layer is deposited on the TCO back contact to a thickness range of 1 nm to 20 nm.

The substrate may be a transparent substrate or a silicon (Si) substrate. The transparent substrate may representatively include glass, and may also include a transparent polymer material.

The Ag precursor layer may be formed using physical vapor deposition such as sputtering, evaporation, or ion-plating. As another example, chemical vapor deposition (CVD) or atomic layer deposition (ALD) may also be used, and any method capable of forming an Ag layer of the above thickness range is usable.

The TCO back contact may representatively include indium tin oxide (ITO), fluorine-doped tin oxide (FTO), indium zinc oxide (IZO), zinc oxide (ZnO), boron-doped zinc oxide (BZO), or the like, but is not limited thereto. Any transparent oxide having high electrical conductivity is usable.

Then, a copper indium gallium selenide (CIGS) light absorbing layer is deposited. In this case, the CIGS light absorbing layer is deposited in a gas or vapor atmosphere including selenium (Se) or sulfur (S).

As shown in (a) of FIG. 3, the CIGS light absorbing layer is formed by depositing indium (In) and gallium (Ga) at a substrate temperature of 300 to 400° C. to form an indium gallium selenide (InGaSe) layer (a first stage), and then depositing and diffusing copper (Cu) at a process temperature equal to or higher than 530° C., to form a CIGS structure (a second stage). Thereafter, In and Ga may be additionally deposited (a third stage) to reduce Cu to below a stoichiometric ratio of Cu/(Ga+In)=1.

According to a modified embodiment, indium gallium sulfide (InGaS) may be formed in the first stage and then the second and third stages may be performed.

Then, a buffer layer and a TCO front contact are sequentially deposited. Optionally, a sodium (Na) compound may be deposited and doped after the third stage and before the buffer layer is formed.

The buffer layer may include CdS, Zn(O,S), ZnSnO, ZnMgO, ZnMgGaO, or the like.

The TCO front contact may include one selected among the above-mentioned materials used for the TCO back contact.

A high-resistivity window layer such as ZnO, ZnMgO, ZnMgGaO, or the like may be included between the buffer layer and the TCO front contact.

FIG. 4 shows the reaction and diffusion of Ag at an interface between the TCO back contact and the InGaSe layer when the CIGS light absorbing layer is formed after the Ag precursor layer is formed. As heat energy is applied and the substrate temperature is increased when the InGaSe layer is formed (i.e., the first stage), reaction occurs between Ag and the InGaSe layer. Ag of a high concentration is present at the interface between the TCO back contact and the InGaSe layer and promotes formation of an Ag-rich selenide layer, which is more advantageous in terms of reaction energy, to suppress Ga-O reaction and formation of gallium oxide (GaOx).

Thereafter, in the second stage, the substrate temperature is increased to a range of 430 to 600° C., and more particularly, of 530 to 580° C. and a CIGS crystal structure and composition is obtained using recrystallization based on deposition and diffusion of Cu on and into an (In,Ga)₂Se₃ precursor. In this case, Ag is uniformly diffused into the CIGS layer in a way that Ag atoms at the interface between the TCO back contact and (In,Ga)₂Se₃ are interchanged with Cu atoms diffused to the interface, but high-concentration Cu atoms are present in a thickness range of 2 nm to 10 nm at the interface between the TCO back contact and CIGS (see (c) of FIG. 4).

Therefore, according to an embodiment of the present invention, when formation of the TCO front contact is lastly completed, as illustrated in (b) of FIG. 3, a CIGS layer corresponding to a Cu-rich region (e.g., a Cu-rich CIGS layer) having a concentration of Cu higher than an average Cu content of the CIGS light absorbing layer is obtained at the interface between the TCO front contact and the Ag-doped CIGS light absorbing layer.

In this case, the average Cu content in the CIGS light absorbing layer refers to an average content value of Cu in a part of the whole CIGS light absorbing layer other than the Cu-rich region which is locally formed at the interface between the TCO front contact and the CIGS light absorbing layer.

Since formation of GaOx is greatly suppressed as described above, GaOx on the TCO front contact is formed to a thickness equal to or less than 3 nm.

Due to a high carrier concentration, the Cu-rich CIGS layer may contribute to an electrically more ohmic interface between the p-doped CIGS light absorbing layer and the n-doped TCO back contact. In addition, since formation of GaOx, which is an n-doped semiconductor, is greatly suppressed, a conventional problem of disturbance of carrier transport by GaOx may be solved.

FIG. 5 shows cross-sectional views showing a cell manufacturing process and a cell structure according to a second embodiment of the present invention. According to the second embodiment of the present invention, the Ag precursor on the TCO back contact may be formed on a molybdenum (Mo) metal pattern. The Mo metal pattern having a window capable of transmitting light therethrough is formed on the TCO back contact by removing Mo by a ratio required for light transmittance, and the Ag precursor is formed on the Mo metal pattern. As such, an electrically more ohmic back contact/CIGS interface is formed between the above structure and a CIGS solar cell formed on the above structure based on Mo contact, and interface adhesion may be increased based on an interface anchoring effect.

According to a modified embodiment, Ag and Mo may be provided as an Ag—Mo alloy layer deposited by co-sputtering an Ag target and a Mo target. In this case, the Ag—Mo alloy layer is provided in a pattern structure having a window capable of transmitting light therethrough, as described above. The Ag—Mo alloy layer serves as the Ag precursor layer. Therefore, when the CIGS light absorbing layer is formed on the Ag—Mo alloy layer, Ag is diffused into the CIGS light absorbing layer and an interface structure in which Cu-rich CIGS is present in a three-dimensional network structure of Mo is formed.

Subsequent processes are the same as those of the afore-described first embodiment, and repeated descriptions will not be provided in all embodiments described below.

FIG. 6 shows cross-sectional views showing a cell manufacturing process and a cell structure according to a third embodiment of the present invention. According to the third embodiment of the present invention, the Ag precursor may be formed on any one of TiOx, TiNbOx, Mo(S, Se)₂ (including MoS₂ and MoSe₂), and MoO₃ layers on the TCO back contact. That is, the TCO back contact is formed, the TiOx, TiNbOx, Mo(S, Se)₂, or MoO₃ layer is formed on the TCO back contact as a back contact top layer, and then the Ag precursor layer is formed on the TiOx, TiNbOx, Mo(S, Se)₂, or MoO₃ layer.

Due to excellent chemical and electrical coherence between the TiOx, TiNbOx, Mo(S, Se)₂, or MoO₃ layer and the CIGS light absorbing layer, interface adhesion may be increased and electrically superior interface characteristics may be achieved.

Test examples capable of supporting the technical features of the present invention will now be described. These test examples are only examples and the present invention is not limited to the test examples.

### EXPERIMENTAL EXAMPLES

Ag precursors having thicknesses of 0 nm and 10 nm were deposited by evaporation on an ITO back contact deposited on a soda-lime glass substrate to a thickness of 600 nm. In, Ga, and Se were deposited at a substrate temperature of 400° C. (a first stage), Cu and Se were deposited by increasing the substrate temperature to 430° C. (a second stage), and In, Ga, and Se were deposited at the same temperature to deposit a Cu-poor CIGS light absorbing layer (a third stage). In this case, a Ga/(In+Ga) ratio was 0.35. A CdS buffer was formed using a chemical bath deposition (CBD) solution process, and then high-resistivity intrinsic ZnO (i-ZnO) and conducting aluminum-doped ZnO (AZO) were deposited to manufacture a cell.

(a) of FIG. 7 shows white light current-voltage characteristics based on whether the Ag precursor was deposited, and (b) and (c) of FIG. 7 show an interface structure between ITO and the CIGS light absorbing layer in a case when the Ag precursor was not deposited and a case when the Ag precursor was deposited, respectively. In addition, (d) and (e) of FIG. 7 show a composition distribution between ITO and the CIGS light absorbing layer in a case when the Ag precursor was not deposited and a case when the Ag precursor was deposited, respectively.

As shown in (a) of FIG. 7, when the Ag precursor was not deposited (ITO_K), carrier transport is disturbed and a current-voltage curve is distorted. On the contrary, when the Ag precursor was deposited to a thickness of 10 nm (ITO_K/Ag), a current-voltage curve is not distorted.

As comparatively shown in (b) and (c) of FIG. 7, since GaOx has a thickness of about 3 nm when the Ag precursor was deposited, but has a thickness of 7 nm when the Ag precursor was not deposited, formation of GaOx is greatly suppressed at the ITO/CIGS light absorbing layer interface.

In addition, referring to (e) of FIG. 7, when the Ag precursor was deposited, a Cu-rich region is present at the ITO/CIGS light absorbing layer interface. Improvement of current-voltage curve characteristics due to use of the Ag precursor as shown in (a) of FIG. 7 is related to GaOx thickness reduction based on suppression of GaOx formation and presence of a Cu-rich composition at the interface.

According to another experimental example, the same technology was applied to a CuGaSe₂ (CGSe) thin film solar cell having a large bandgap. Ag precursors having thicknesses of 10 nm, 20 nm, and 40 nm were deposited by evaporation on an ITO back contact deposited on a soda-lime glass substrate to a thickness of 200 nm. Ga and Se were deposited at a substrate temperature of 400° C. (a first stage), Cu and Se were deposited by increasing the substrate temperature to 550° C. (a second stage), and Ga and Se were deposited at the same temperature to deposit a Cu-poor CGSe light absorbing layer (a third stage). A CdS buffer was formed using a CBD solution process, and then high-resistivity i-ZnO and conducting AZO were deposited to manufacture a cell.

As shown in (a) of FIG. 8, until the thickness of the Ag precursor is increased to 20 nm, all the solar parameters, open-circuit voltage (V_{OC}), short-circuit current (J_{SC}), and a fill factor (FF), are greatly improved due to use of the Ag precursor. However, when the thickness of the Ag precursor is further increased to 40 nm, V_{OC} and J_{SC} are reduced.

(b) of FIG. 8 shows a variation in a microstructure based on the increase in the thickness of the Ag precursor. Until the thickness of the Ag precursor is increased to 20 nm, grain sizes are increased due to use of the Ag precursor. However, when the thickness of the Ag precursor is further increased to 40 nm, grain sizes are greatly reduced. It may be concluded that the variation in the microstructure matches the above-described variation in photovoltaic conversion efficiency.

Table 1 shows a result of measuring the composition of the CGSe light absorbing layer based on electron probe microanalysis (EPMA). The compositions of Ag in Experimental examples 2 and 3 showing excellent efficiency characteristics were only 0.78 at % and 1.39 at %, respectively. The above result of analyzing the composition of the CGSe light absorbing layer shows that performance of the CGSe thin film solar cell manufactured by doping Ag using the Ag precursor may be improved using only a very small amount of Ag of about 1 at % to 2 at %.

Table 1 shows a result of measuring the composition of the light absorbing layer of FIG. 7 based on EPMA.

TABLE 1

| Sample | Sample | Composition (at %, atomic percent) | | | |
|---|---|---|---|---|---|
| Name | Structure | Ag | Cu | Ga | Se |
| Experimental | ITO | 0 | 24.28 | 25.31 | 50.38 |
| example 1 | | | | | |
| Experimental | ITO/Ag 10 nm | 0.78 | 21.82 | 26.36 | 50.98 |
| example 2 | | | | | |
| Experimental | ITO/Ag 20 nm | 1.39 | 21.83 | 25.97 | 50.77 |
| example 3 | | | | | |
| Experimental | ITO/Ag 40 nm | 2.51 | 22.76 | 25.05 | 49.65 |
| example 4 | | | | | |

Then, an Ag doping effect based on an Ag precursor method according to the technical features of the present invention is now compared to an Ag doping effect based on co-evaporation according to a comparative example. Ag is equally doped to a thickness of 20 nm.

Specifically, to analyze the effect of the Ag precursor method, a sample was prepared by forming an Ag precursor on ITO and then depositing Ga and Se at a substrate temperature of 400° C. To analyze the effect based on co-evaporation, a sample was prepared by co-evaporating Ag in the middle of the process of depositing Ga and Se at the substrate temperature of 400° C. In each of the two samples prepared as described above, a concentration profile of Ag in a thickness direction of the sample from the surface of a CGSe light absorbing layer was analyzed based on atomic emission spectrometry (AES), and is shown in (b) of FIG. 9.

Based on the Ag precursor method, the Ag precursor is formed on the surface of ITO as shown in (a) of FIG. 9 and thus Ag has a high concentration near the surface of ITO (see “Ag precursor” in (b) of FIG. 9). When Ag is co-evaporated in the middle while Ga₂Se₃ is being deposited, Ag has a high concentration in the middle of the Ga₂Se₃ layer (see “Ag codep.” in (b) of FIG. 9). This shows that a diffusing speed of Ag in the Ga₂Se₃ layer is restrictive at 400° C. Therefore, based on the Ag precursor method, since the Ga₂Se₃ layer is formed when diffusion of Ag is restricted as described above, the concentration of Ag at a back contact interface may be maintained to be high until CGS recrystallization of a second stage is started.

FIG. 10 shows ITO/CGSe interface structures of CGSe solar cells manufactured using the Ag doping methods of FIG. 9 (i.e., a method of depositing an Ag precursor and a method of co-evaporating Ag in the middle of a first stage), a method of not doping Ag, and a method of co-evaporating Ag at the beginning of a second stage, respectively.

The thickness of formed GaOx is large in the order of the method of not doping Ag ((a) of FIG. 10), the method of co-evaporating Ag at the beginning of the second stage ((d) of FIG. 10), the method of co-evaporating Ag in the middle of the first stage ((c) of FIG. 10), and the method of depositing the Ag precursor ((b) of FIG. 10). That is, the later Ag is supplied, the larger thickness GaOx has.

Similarly to use of a CIGS light absorbing layer, when Ag is supplied in the form of a precursor, unlike the other cases, a Cu-rich region exceeding a CGSe stoichiometric ratio is present in a thickness of about 5 nm on the surface of ITO. As described above, Ag atoms at the ITO/CGSe interface and Cu atoms diffused to the interface are interdiffused in the second stage of deposition and thus the Cu-rich region having high-concentration Cu atoms are present at the ITO/CGSe interface. It may be concluded that the Cu-rich region results in more ohmic electrical characteristics between the CGSe light absorbing layer and the ITO back contact.

As another experimental example, samples were prepared by forming TiOx (1 nm), TiNbOx (TNO) (1 nm), and MoS₂ (5 nm) on an ITO back contact and then depositing an Ag precursor on TiOx, TNO, and MoS₂, and then current flow characteristics (j-V) of solar cells were compared.

As shown in FIG. 11, when the Ag precursor was not deposited, TiOx and TNO partially disturb the flow of current at the solar cell back contact interface, but MoS₂ does not disturb the flow of current. That is, it may be concluded that the interface between MoS₂ and a CGSe light absorbing layer is electrically more ohmic similarly to the ITO/Ag precursor interface.

When the Ag precursor is deposited on the TiOx, TNO, and MoS₂ layers, current flow characteristics almost equal to those of the ITO/Ag precursor structure are achieved.

Additionally, unlike conventional technology, the Ag precursor method according to the technical features of the present invention may increase adhesion of an ITO/CGSe light absorbing layer interface in a Si substrate. Since Si has a very small thermal expansion coefficient compared to soda-lime glass, a large difference in thermal expansion is present between Si and CGSe. Therefore, in general, when the CGSe light absorbing layer is deposited on the Si substrate, the CGSe light absorbing layer is peeled off as shown in (a) of FIG. 12. However, when the Ag precursor is formed on ITO and then the CGSe light absorbing layer is deposited on the Ag precursor, a solar cell may be stably manufactured without interface peeling as shown in (b) of FIG. 12.

When a crystalline Si (c-Si)/ITO cell and a CGSe cell are monolithically integrated into a tandem cell, to define Si cell area, an emitter region other than the cell area is chemically or physically etched. A CGSe light absorbing layer grown on Si exposed outside the cell area is easily peeled off and thus upper-lower cell shunting easily occurs as shown in (a) of FIG. 13. In this case, if a TiOx layer is formed on c-Si/ITO and an Ag precursor is deposited on the TiOx layer, a tandem cell may be successfully manufactured without interface peeling as shown in (b) of FIG. 13, and cell characteristics related to efficiency may be improved as shown in (c) of FIG. 13. It may be concluded that the above effects are achieved because chemical affinity between TiOx and CGSe is excellent.

FIG. 14 shows an example of a process of manufacturing a tandem cell by inserting an ITO intermediate contact and a TiOx/Ag precursor between a crystalline Si (c-Si) solar cell and a CGSe solar cell. Initially, spin-on-glass (SOG) layer is spin-coated to form an n-doped emitter on the surface of a p-doped Si wafer, an aluminum (Al) back contact is evaporated at an opposite side of the Si wafer, and then the Si wafer is annealed at 900° C. and is cleaned in hydrofluoric acid (HF).

Thereafter, ITO is deposited on the emitter, and then a region other than a solar cell area is wet- or dry-etched to remove ITO and the Si emitter therefrom. A TiOx layer and an Ag precursor layer are sequentially deposited thereon, and then a CGSe light absorbing layer, a CdS buffer layer, high-resistivity ZnO, and an AZO layer are formed. Lastly, a grid pattern is formed for current collection. After the TiOx layer is deposited, heat treatment may be performed in a hydrogen atmosphere at a substrate temperature of 400° C. for 30 minutes.

FIG. 15 shows the structure and photovoltaic conversion efficiency of a c-Si/ITO/CGSe tandem cell manufactured using the process of FIG. 14. An ITO intermediate contact structure according to the present invention is successfully formed, leading to no reduction in efficiency due to processes of upper and lower cells, and a cell efficiency of 9.7%, which is the highest ratio in the world up to now, is achieved.

1. A chalcogenide solar cell comprising:
a substrate;
a transparent conducting oxide (TCO) back contact provided on the substrate;
a chalcogenide light absorbing layer provided on the TCO back contact and comprising at least copper (Cu), gallium (Ga), and silver (Ag); and
a TCO front contact provided on the chalcogenide light absorbing layer,
wherein a Cu-rich region having a content of Cu higher than an average Cu content of the chalcogenide light absorbing layer is provided at an interface where the chalcogenide light absorbing layer is in contact with the TCO back contact.

2. The chalcogenide solar cell of claim 1,
wherein gallium oxide (GaOx) having a thickness equal to or less than 3 nm is provided on the TCO back contact.

3. The chalcogenide solar cell of claim 1,
wherein the chalcogenide light absorbing layer comprises Cu(InₓGa₁₋ₓ)(Se_{y},S_{1-y}) (0.2<x≤1, 0≤y≤1).

4. The chalcogenide solar cell of claim 1,
wherein the Cu-rich region has a thickness ranging from 2 nm to 10 nm.

5. The chalcogenide solar cell of claim 1,
wherein the content of Ag in the chalcogenide light absorbing layer is greater than 0 atomic percent (at %) and equal to or less than 2 at %.

6. The chalcogenide solar cell of claim 1,
further comprising a molybdenum (Mo) layer between the Cu-rich region and the TCO back contact,
wherein the Mo layer is provided as a pattern generated by coating only a part of the TCO back contact and comprising a window capable of transmitting light therethrough.

7. The chalcogenide solar cell of claim 1,
wherein one or more of titanium oxide (TiOx), niobium-doped titanium oxide (TiNbOx), Mo(S, Se)₂, and MoO₃ layers are provided between the Cu-rich region and the TCO back contact.

8. The chalcogenide solar cell of claim 1,
wherein the content of Cu in the Cu-rich region is higher than the average Cu content of the chalcogenide light absorbing layer by 10 at % to 20 at %.

9. The chalcogenide solar cell of claim 1,
wherein the substrate comprises a transparent substrate or a crystalline silicon (c-Si) substrate.

10. A method of manufacturing a chalcogenide solar cell, the method comprising:
forming a transparent conducting oxide (TCO) back contact on a first surface of a substrate;
forming a silver (Ag) precursor layer on the TCO back contact;
forming a chalcogenide light absorbing layer comprising copper (Cu) and gallium (Ga), on the TCO back contact; and
forming a TCO front contact on the chalcogenide light absorbing layer,
wherein the forming of the chalcogenide light absorbing layer comprises:
diffusing the Ag precursor layer into the chalcogenide light absorbing layer; and
forming a Cu-rich region having a content of Cu higher than an average Cu content of the chalcogenide light absorbing layer, at an interface where the chalcogenide light absorbing layer is in contact with the TCO back contact.

11. The method of claim 10,
wherein the chalcogenide light absorbing layer comprises Cu(InₓGa₁₋ₓ)(Se_{y},S_{1-y}) (0.2<x≤1, 0≤y≤1).

12. The method of claim 10,
wherein the forming of the chalcogenide light absorbing layer comprises:
a first stage for forming a gallium selenide layer or a gallium sulfide layer by depositing Ga and selenium (Se), or Ga and sulfur (S), on the TCO back contact; and
a second stage for coating and diffusing Cu and Se, or Cu and S, on and into the gallium selenide layer or the gallium sulfide layer.

13. The method of claim 10,
wherein the forming of the chalcogenide light absorbing layer comprises:
a first stage for forming an indium gallium selenide layer or an indium gallium sulfide layer by depositing Ga, indium (In) and Se, or Ga, In and S, on the TCO back contact; and
a second stage for coating and diffusing Cu and Se, or Cu and S, on and into the indium gallium selenide layer or the indium gallium sulfide layer.

14. The method of claim 12,
wherein the diffusing of the Ag precursor layer into the chalcogenide light absorbing layer and the forming of the Cu-rich region are performed in the second stage.

15. The method of claim 12,
wherein the first stage is performed at a temperature in the range of 300□ to 400□.

16. The method of claim 12, wherein the second stage is performed at a temperature in the range of 430□ to 600□.

17. The method of claim 11, further comprising:
forming a molybdenum (Mo) layer as a pattern generated by coating only a part of the TCO back contact and comprising a window capable of transmitting light therethrough, after the TCO back contact is formed.

18. The method of claim 10,
wherein the Ag precursor layer comprises pure Ag.

19. The method of claim 10,
wherein the Ag precursor layer comprises an alloy of molybdenum (Mo) and silver (Ag), and is formed as a pattern generated by coating only a part of the TCO back contact and comprising a window capable of transmitting light therethrough.

20. The method of claim 10, further comprising:
forming one or more of titanium oxide (TiOx), niobium-doped titanium oxide (TiNbOx), Mo(S, Se)₂, and MoO₃ layers on the TCO back contact after the TCO back contact is formed.

21. The method of claim 10,
wherein the Ag precursor layer has a thickness ranging from 1 nm to 20 nm.

22. The method of claim 21,
wherein the Ag precursor layer has a thickness ranging from 10 nm to 20 nm.

23. The method of claim 13,
wherein the diffusing of the Ag precursor layer into the chalcogenide light absorbing layer and the forming of the Cu-rich region are performed in the second stage.

24. The method of claim 13,
wherein the first stage is performed at a temperature in the range of 300□ to 400□.

25. The method of claim 13,
wherein the second stage is performed at a temperature in the range of 430□ to 600□.
